(19) United States
(12) Patent Application Publication
(10) Pub. No.: US 2025/0079207 A1
(43) Pub. Date: Mar. 6, 2025

(54) METHODS AND MECHANISMS FOR VIBRATION MONITORING

(71) Applicant: Applied Materials, Inc., Santa Clara, CA (US)

(72) Inventors: Punyabrahma Panda, Bangalore (IN); Tao Zhang, San Ramon, CA (US); Ganapathy Saravanavel, Madurai (IN); Zhi Wang, Redwood City, CA (US)

(21) Appl. No.: 18/242,886

(22) Filed: Sep. 6, 2023

(51) Int. Cl. H01L 21/67; C23C 16/52; G01H 1/00; H04Q 9/00

(52) U.S. Cl. CPC H01L 21/67242; C23C 16/52; G01H 1/00; H04Q 9/00

(57) ABSTRACT

An electronic device manufacturing system is provided that includes a monitoring system coupled to a tool. The monitoring system comprises a body to mount to a surface of a tool; a vibration detecting sensor disposed in or on the body, the vibration detecting sensor to generate a signal based on a vibration of the surface; a wired communication device disposed in or on the body, wherein in a first configuration the wired communication device is to transmit the signal generated by the vibration detecting sensor to the computer system via a wired connection with the computer system; and a wireless communication device disposed in or on the body, wherein in a second configuration the wireless communication device is to establish a wireless connection with the computer system and to transmit the signal generated by the vibration detecting sensor to the computer system via the wireless connection.

### TECHNICAL FIELD

Embodiments of the present disclosure relate to vibration monitoring, and, more particularly, to methods and mechanisms for vibration monitoring.

### BACKGROUND

Products can be produced by performing one or more manufacturing processes using manufacturing equipment. For example, semiconductor manufacturing equipment can be used to produce semiconductor devices (e.g., substrates) via semiconductor manufacturing processes. The manufacturing equipment can, according to a process recipe, deposit multiple layers of film on the surface of the substrate and can perform an etch process to form the intricate pattern in the deposited film. For example, the manufacturing equipment can perform a chemical vapor deposition (CVD) process to deposit alternative layers on the substrate. Etch process equipment can then be used to remove material from areas of a substrate through, e.g., chemical reaction and/or physical bombardment.

Sensors can be used to determine manufacturing parameters of the manufacturing equipment during the manufacturing processes and metrology equipment can be used to determine property data of the products that were produced by the manufacturing equipment, such as the overall thickness of the layers on the substrate.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, an electronic device manufacturing system is provided that includes a monitoring system coupled to (e.g., mounted to or otherwise attached to) a tool of the electronic device manufacturing system. The monitoring system comprises a body to mount to a surface of a tool, a vibration detecting sensor disposed in or on the body, a wired communication device disposed in or on the body, and a wireless communication device disposed in or on the body. The vibration detecting sensor can generate a signal based on a vibration of the surface. In a first configuration, the wired communication device is to transmit the signal generated by the vibration detecting sensor to the computer system via a wired connection with the computer system. In a second configuration the wireless communication device is to establish a wireless connection with the computer system and to transmit the signal generated by the vibration detecting sensor to the computer system via the wireless connection.

In another aspect of the disclosure, a monitoring system is provided. The monitoring system comprises a body to mount to a surface of a tool, a vibration detecting sensor disposed in or on the body, a wired communication device disposed in or on the body, and a wireless communication device disposed in or on the body. The vibration detecting sensor can generate a signal based on a vibration of the surface. In a first configuration, the wired communication device is to transmit the signal generated by the vibration detecting sensor to the computer system via a wired connection with the computer system. In a second configuration the wireless communication device is to establish a wireless connection with the computer system and to transmit the signal generated by the vibration detecting sensor to the computer system via the wireless connection.

In another aspect of the disclosure, a method is provided. The method includes generating, by a monitoring device mounted to a tool of an electronic device manufacturing system, vibration data associated with the tool. The monitoring system comprises a body to mount to a surface of a tool, a vibration detecting sensor disposed in or on the body, a wired communication device disposed in or on the body, and a wireless communication device disposed in or on the body. The vibration detecting sensor can generate a signal based on a vibration of the surface. In a first configuration, the wired communication device is to transmit the signal generated by the vibration detecting sensor to the computer system via a wired connection with the computer system. In a second configuration the wireless communication device is to establish a wireless connection with the computer system and to transmit the signal generated by the vibration detecting sensor to the computer system via the wireless connection.

### BRIEF DESCRIPTION OF THE DRAWINGS

The present disclosure is illustrated by way of example, and not by way of limitation in the figures of the accompanying drawings.

FIG. 1 is a block diagram illustrating an example operating environment, in accordance with some implementations of the present disclosure.

FIG. 2 is a top schematic view of an example manufacturing system, in accordance with some implementations of the present disclosure.

FIG. 3 depicts a metrology system of a substrate manufacturing system, in accordance with some implementations of the present disclosure.

FIG. 4 is a block diagram of an example monitoring system, in accordance with some implementations of the present disclosure.

FIGS. 5A-5C depict respective side views of different example shapes of the base of a monitoring system, in accordance with some implementations of the present disclosure.

FIG. 6 depicts an example monitoring system, in accordance with some implementations of the present disclosure.

FIG. 7 depicts another example monitoring system, in accordance with some implementations of the present disclosure.

FIG. 8 illustrates an example user interface of an application displayed on a client device, in accordance with some implementations of the present disclosure.

FIG. 9 is a flow chart of a method for generating and sending vibration data, in accordance with some implementations of the present disclosure.

FIG. 10 is a flow chart of a method for displaying vibration data by a client device, in accordance with some implementations of the present disclosure.

FIG. 11 is a block diagram illustrating a computer system, in accordance with some implementations of the present disclosure.

### DETAILED DESCRIPTION

Described herein are technologies directed to methods and mechanisms for vibration monitoring in, for example, metrology equipment at a manufacturing system. In substrate manufacturing, a film can be deposited on a surface of a substrate during a deposition process (e.g., a deposition (CVD) process, an atomic layer deposition (ALD) process, and so forth) performed at a process chamber of a manufacturing system. For example, in a CVD process, the substrate is exposed to one or more precursors, which react on the substrate surface to produce the desired deposit. The film can include one or more layers of materials that are formed during the deposition process, and each layer can include a particular thickness gradient (e.g., changes in the thickness along a layer of the deposited film).

The film can be subjected to, for example, an etch process to form a pattern on the surface of the substrate, a chemical-mechanical polishing/planarization (CMP) process to smooth the surface of the film, or any other process necessary to manufacture the finished substrate. An etch process can include exposing highly energetic process gas (e.g., a plasma) with a sample surface to break down the materials at the surface, which can then be removed by a vacuum system.

A process chamber can perform each substrate manufacturing process (e.g., the deposition process, the etch process, the polishing process, etc.) according to a process recipe. A process recipe defines a particular set of operations to be performed for the substrate during the process and can include one or more settings associated with each operation. For example, a deposition process recipe can include a temperature setting for the process chamber, a pressure setting for the process chamber, a flow rate setting for a precursor for a material included in the film deposited on the substrate surface, etc. Accordingly, the thickness of each film layer can be correlated to these process chamber settings. Execution of a process recipe in a process chamber can be referred to as a process run.

Metrology can be performed during, before and/or after processing to determine whether substrates are achieving target performance thresholds. Actions can be taken based on metrology measurements, such as initiating maintenance, updating process recipes, aborting process procedures, modifying downstream process procedures, etc. Accuracy, resolution, and reliability of metrology techniques can have a great impact upon efficiency, agility, and/or certainty of actions taken in response to measured substrate properties.

In some systems, metrology measurements can be performed in a process chamber, in a process tool, under process (e.g., vacuum) conditions, in a process environment, etc. In some systems, metrology measurements can be performed in a metrology system that can be connected to or within a transfer chamber or factory interface to which chambers can also be connected (referred to as “in-situ metrology” or “in-situ metrology system”). Chambers connected to a manufacturing system can include process chambers, deposition chambers, etch chambers, anneal chambers, metrology chambers, multi-use chambers, etc. In some systems, an in-situ metrology system can suffer from interference by components of the processing system. For example, various pumps, motors, valves, fans, actuators, etc., can introduce vibrations that can interfere with one or more measurements of substrate properties. Further, outside influence, such as objects colliding with a process system, influences of other process systems or other elements of a building housing the process system, etc., can induce motion that interferes with metrology measurements.

To filter out this interference, some systems can use an accelerometer to record acceleration data and filter out the disturbances post-processing. However, current systems are bulky, heavy, costly, and may be difficult to couple to certain portions of a metrology system. The size and weight of these system can affect the resonance frequency of the accelerometer, thus generating erroneous results. In addition, current systems lack supporting software and diversified data communication components.

Aspects and implementations of the present disclosure address these and other shortcomings of the existing technology by providing a lightweight and versatile system configured to provide vibration monitoring in metrology equipment at a manufacturing system. In particular, methods, systems, and devices of the present disclosure can be utilized in determining the external vibration experienced by in-situ metrology equipment due to vibrations generated by a process chamber, load lock, aligner station, transfer chamber, factory interface, fans and other components of the manufacturing system. The present disclosure can enable adjusting operations of a substrate manufacturing system in view of detected vibration. Aspects of the present disclosure can include a vibration monitoring system (hereafter “monitoring system”) and user interface (UI) component. The monitoring system can be designed as a light-weight compact, and versatile system capable of being coupled to (e.g., mounted to, attached to, connected to, etc.) different type of surfaces of metrology equipment. In some implementations, the monitoring system can include a body (such as a housing), a vibration detecting sensor (e.g., an accelerometer), a power component for supplying power to the monitoring system, a signal processing component for filtering and converting the signal captured by the vibration detecting sensor, and multiple data communication devices (e.g., both a wired connector and a wireless device, such as a Bluetooth device or a WiFi device). In some implementations, the monitoring system can be approximately 5-60 mm in height, in width, and in length. In some implementations, the size and/or dimensions of the monitoring system can be correlated to the type of vibration detecting sensor used. For example, if the base of a vibration detecting sensor is approximately 100 mm², the volume of the monitoring system can be made to be less than 200 mm³. In some implementations, the vibration detecting sensor can be coupled to a rigid or flexible substrate (e.g., a printed circuit board (PCB)), where each monitoring system can be fabricated in a particular size depending on user requirements. The flexible substrate can allow the monitoring system to be mounted on other than flat surfaces of the metrology equipment, such as concave or convex surfaces. In some implementations, the substrate can be mounted on the surface of the metrology equipment. In other implementations, the body of the monitoring system can be mounted one the surface of the metrology equipment. In some implementations, the monitoring system can include a single wired connector, such as an international electrotechnical commission (IEC) connector or a Japan Solderless Terminal (JST) connector, that is configured to supply power to the monitoring system and output data from the monitoring system.

The accelerometer data can be received by an application presenting a user interface on a client device. The user interface (UI) can present the acceleration data, can present velocity data and/or displacement data obtained from the acceleration data, can provide filtering options for selection, can display frequency component of the signal obtained from the accelerometer, etc. The accelerometer data can be provided to the application in real-time or near real-time.

Aspects of the present disclosure result in technological advantages over traditional systems. In particular, the monitoring system of the present disclosure can be lightweight and versatile and without adding bulky or additional hardware to the monitoring system that can affect the resonance frequency of the accelerometer and cause erroneous results. In certain aspects, the monitoring system can increase (or maintain or prevent noticeable change) the resonance frequency of the accelerometer of the monitoring system, thus better preventing vibrations experienced the monitoring system from affecting the results generated by the accelerometer (as in contrast with other systems which typically decrease the resonance frequency of an accelerometer and thus increase the vibrations experienced by an accelerometer). The monitoring system of the present disclosure can further be designed to be coupled to different surface structures (e.g., flat surfaces, concave surfaces, convex surfaces, etc., thus allowing a monitoring system to be coupled to any part of the metrology system. By measuring vibration of a metrology system, costly actions taken in view of unreliable measurements may be avoided. Aspects of the present disclosure further provide advanced UI capabilities for real or near-real time monitoring of vibrations. This may prevent costly unscheduled downtime or unscheduled preventive maintenance, which may increase manufacturing system productivity and throughput, and may decrease costs associated with unscheduled downtime such as repair time, re-seasoning time, express shipping for replacement components, etc.

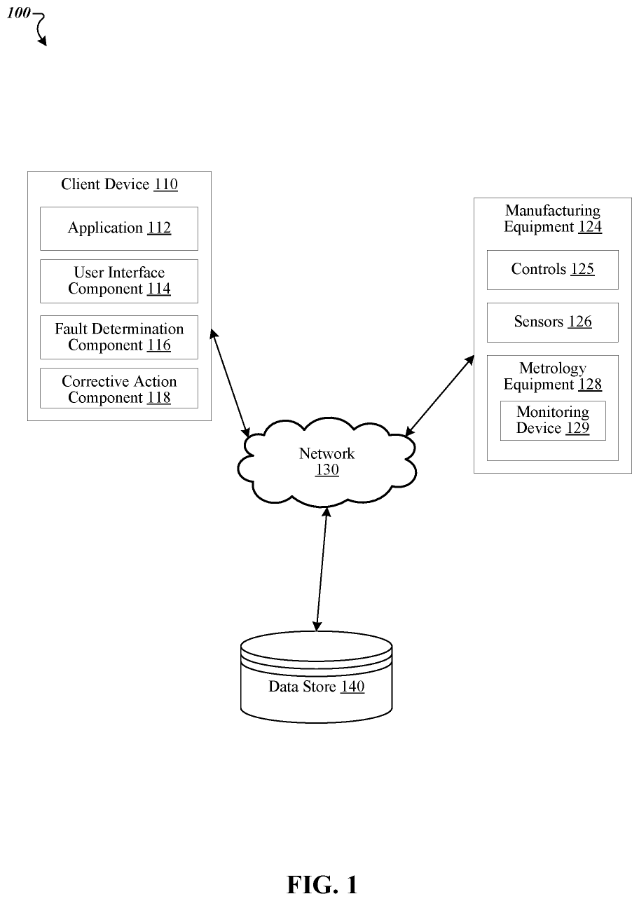

FIG. 1 depicts an illustrative operating environment 100, according to aspects of the present disclosure. In some implementations, operating environment 100 can be included as part of a manufacturing system for processing substrates. Operating environment 100 includes a client device 110, manufacturing equipment 124, and data store 140.

Manufacturing equipment 124 can produce products, such as electronic devices, following a recipe or performing runs over a period of time. Manufacturing equipment 124 can include a process chamber and can perform a process for a substrate (e.g., a wafer, etc.) at the process chamber. Examples of substrate processes include a deposition process to deposit one or more layers of film on a surface of the substrate, an etch process to form a pattern on the surface of the substrate, etc. Manufacturing equipment 124 can perform each process according to a process recipe. A process recipe defines a particular set of operations to be performed for the substrate during the process and can include one or more settings associated with each operation. For example, a deposition process recipe can include a temperature setting for the process chamber, a pressure setting for the process chamber, a flow rate setting for a precursor for a material included in the film deposited on the substrate surface, etc.

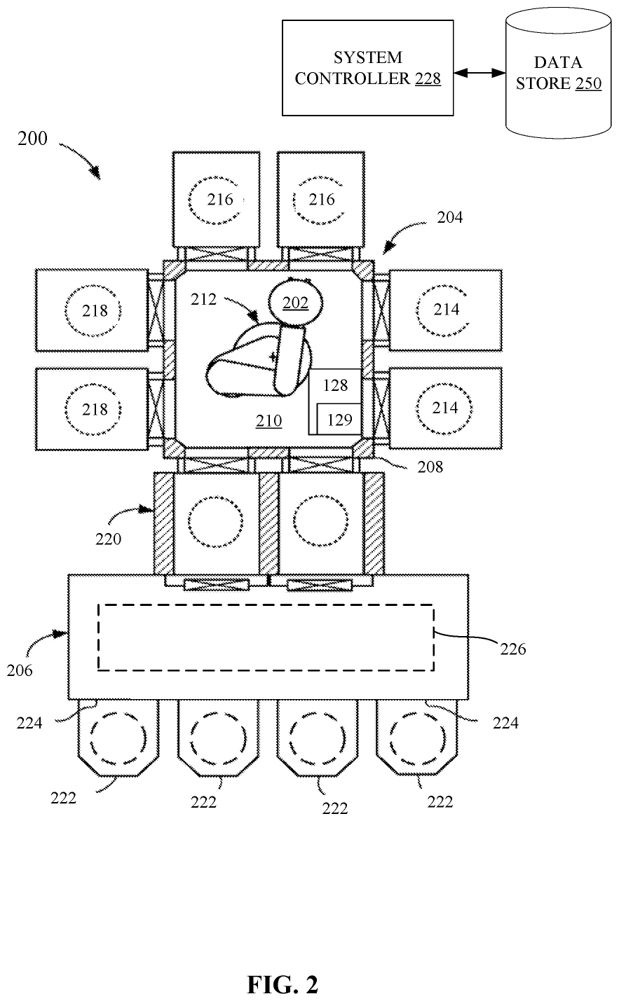

The manufacturing equipment 124 can include sensors 126 configured to capture data for a substrate being processed at the manufacturing system. In some implementations, the manufacturing equipment 124 and sensors 126 can be part of a sensor system that includes a sensor server (e.g., field service server (FSS) at a manufacturing facility) and sensor identifier reader (e.g., front opening unified pod (FOUP) radio frequency identification (RFID) reader for sensor system). Sensors 126 can be configured to generate data associated with a substrate processed at operating environment 100. For example, a process chamber can include one or more sensors configured to generate spectral or non-spectral data associated with the substrate before, during, and/or after a process (e.g., a deposition process, an etch process, etc.) is performed for the substrate. In some implementations, spectral data generated by sensors 126 can indicate a concentration of one or more materials deposited on a surface of a substrate. Sensors 126 configured to generate spectral data associated with a substrate can include reflectometry sensors, ellipsometry sensors, thermal spectra sensors, capacitive sensors, and so forth. Sensors 126 configured to generate non-spectral data associated with a substrate can include temperature sensors, pressure sensors, flow rate sensors, voltage sensors, etc. For example, each sensor 126 can be a temperature sensor, a pressure sensor, a chemical detection sensor, a chemical composition sensor, a gas flow sensor, a motion sensor, a position sensor, an optical sensor, or any and other type of sensors. Some or all of the sensors 126 can include a light source to produce light (or any other electromagnetic radiation), direct it towards a target, such as a component of the operating environment 100 or a substrate, a film deposited on the substrate, etc., and detect light reflected from the target. The sensors 126 can be located anywhere inside the manufacturing equipment 124 (for example, within any of the chambers including the loading stations, on one or more robots, on a robot blade, between the chambers, and so one), or even outside the manufacturing equipment 124 (where the sensors can test ambient temperature, pressure, gas concentration, and so on). Further details regarding manufacturing equipment 124 are provided with respect to FIG. 2.

In some implementations, sensors 126 provide sensor data (e.g., sensor values, features, trace data) associated with manufacturing equipment 124 (e.g., associated with producing, by manufacturing equipment 124, corresponding products, such as substrates). The manufacturing equipment 124 can produce products following a recipe or by performing runs over a period of time. Sensor data received over a period of time (e.g., corresponding to at least part of a recipe or run) can be referred to as trace data (e.g., historical trace data, current trace data, etc.) received from different sensors 126 over time. Sensor data can include a value of one or more of temperature (e.g., heater temperature), spacing, pressure, high frequency radio frequency, voltage of electrostatic chuck, electrical current, material flow, power, voltage, etc. Sensor data can be associated with or indicative of manufacturing parameters such as hardware parameters, such as settings or components (e.g., size, type, etc.) of the manufacturing equipment 124, or process parameters of the manufacturing equipment 124. The sensor data can be provided while the manufacturing equipment 124 is performing manufacturing processes (e.g., equipment readings when processing products). The sensor data can be different for each substrate.

In some implementations, manufacturing equipment 124 can include controls 125. Controls 125 can include one or more components or sub-systems configured to enable and/or control one or more processes of manufacturing equipment 124. For example, a sub-system can include a pressure sub-system, a flow sub-system, a temperature sub-system and so forth, each sub-system having one or more components. The component can include, for example, a pressure pump, a vacuum, a gas deliver line, a plasma etcher, actuators etc. In some implementations, controls 125 can be managed based on data from sensors 126, input from client device 110, etc.

In some implementations, metrology equipment 128 can be part of manufacturing equipment 124 and can include a metrology server (e.g., a metrology database, metrology folders, etc.) and metrology identifier reader (e.g., FOUP RFID reader for metrology system). Metrology equipment 128 can provide metrology data associated with substrates processed by manufacturing equipment 124. The metrology data can include a value of film property data (e.g., wafer spatial film properties), dimensions (e.g., thickness, height, etc.), dielectric constant, dopant concentration, density, defects, etc. In some implementations, the metrology data can further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data can be of a finished or semi-finished product. The metrology data can be different for each substrate. Metrology data can be generated using, for example, reflectometry techniques, ellipsometry techniques, transmission electron microscopy techniques, and so forth.

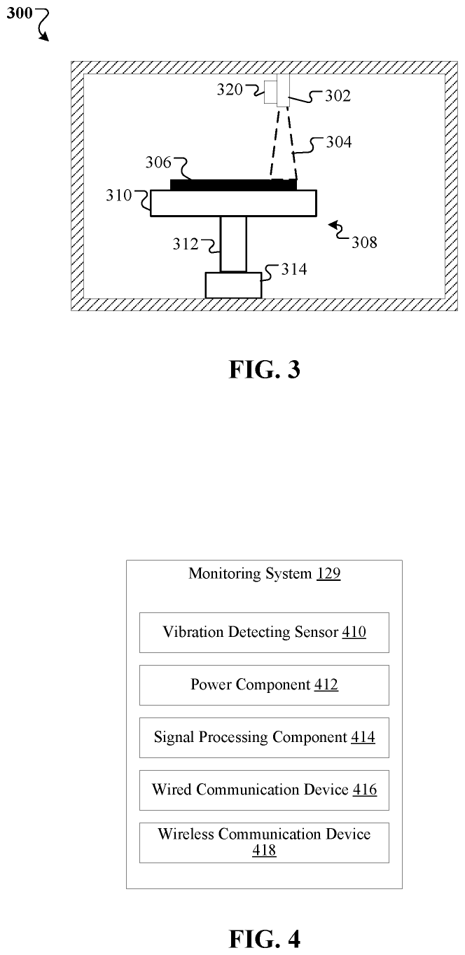

In some implementations, metrology equipment 128 can be included as part of the manufacturing equipment 124, as shown in FIG. 1. For example, metrology equipment 128 can be included inside of or coupled to a process chamber and configured to generate metrology data for a substrate before, during, and/or after a process (e.g., a deposition process, an etch process, etc.) while the substrate remains in the process chamber. In some instances, metrology equipment 128 can be referred to as in-situ metrology equipment. In another example, metrology equipment 128 can be coupled to another station of manufacturing equipment 124. For example, metrology equipment can be coupled to a transfer chamber, such as transfer chamber 210 of FIG. 2, a load lock, such as load lock 220, or a factory interface, such as factory interface 206. In some implementations, metrology equipment 128 can be a standalone system (not shown) connected to network 130 and part of operating environment 100. Further details regarding metrology equipment 128 are provided with respect to FIG. 3.

Metrology equipment can include monitoring system 129. Monitoring system 129 can provide real-time, near real-time, or historical data related to vibrations or shock experienced by monitoring system 129. Vibration can include is a periodic or random oscillating force that occurs about a point of equilibrium. Shock can include a transient condition where the equilibrium of a system is disrupted by a sudden applied force. In some implementations, monitoring system 129 can be coupled to metrology equipment 128. The term “coupled to” can refer to any one of mounted to, attached to, connected to, affixed to, connected to, and so forth. For example, monitoring system 129 can be coupled to metrology equipment 128 using adhesive, bolts, screws, epoxy, cables, brackets, magnets, or any other suitable method.

FIG. 4 is a diagram of an example monitoring system 129, according to aspects of the present disclosure. Monitoring system 129 can include vibration detecting sensor 410, power component 412, signal processing component 414, wired communication device 416, wireless communication device 418.

Vibration detecting sensor 410 can be any device configured to detect vibrations (or shock) experienced by monitoring system 129. In some implementations, vibration detecting sensor 410 can include an accelerometer, which is a device that measures the acceleration of motion of a structure. In an illustrative example, vibration detecting sensor can be a micro-electro-mechanical systems (MEMS) accelerometer. MEMS accelerometers can measure linear motion (movement, shock, vibration, etc.) without a fixed reference. In particular, a MEMS accelerometer can measure the linear acceleration of whatever it is coupled with, such as, for example, metrology equipment 128. In some implementations, the accelerometer can include a certain range of measurable forces (e.g., from ±1 g to ±250 g). For example, the accelerometer can include a range of ±1 g to ±2 g, ±1 g to ±10 g, etc. In other implementations, vibration detecting sensor 410 can include a strain gauge, an Eddy-Current sensor, a laser displacement sensor, a gyroscope, a microphone, a vibration meter, etc.

Power component 412 can supply power to monitoring system 129 (or to the vibration detecting sensor 410). Power component 412 can include one or more of a battery (e.g., lithium battery, alkaline battery, rechargeable battery, button battery, etc.), a power connector (e.g., a device that allows an electrical current to pass through it for the purpose of providing power to a device monitoring system 129), a power converter (e.g., a device that converts AC power to DC power), a power transformer (e.g., a device that converts voltage from a high voltage to a low voltage, or vice versa), etc. In an illustrative example, 24V (volt) DC power can be supplied to manufacturing equipment 124, and power component 412 (via a power transformer) can convert the 24V DC power to 3.3V power and supply the 3.3V power to monitoring system 129. In implementations where the power component 412 is a battery, the weight of the battery can be significantly less than the overall weight of monitoring system 129. For example, the mass (or the weight) of the battery can be at least ten times less than the mass (or weight) of monitoring system 129. This can prevent change (or prevent noticeable change) in the resonance frequency of monitoring system 129, thus preventing the battery from affecting the measurement generated by vibration detecting sensor 410.

Signal processing component 414 can be configured to condition, and/or convert the signal captured (raw signal) by the vibration detecting sensor 410. In particular, signal processing component 414 can condition the raw signal by amplifying one or more characteristics of the signal (e.g., amplifying a voltage, current, charge, etc.), filtering (removing) certain components or features (e.g., unwanted signals such as noise or interference) from the raw signal obtained by vibration detecting sensor 410, etc. For example, signal processing component 414 can include a direct current (DC) blocking notch filter or envelope detection method to remove a buildup DC signal generated by power component 412. In some implementations, signal processing component 414 can use one or more additional methods and/or filters to process the raw signal, including but not limited to, a Butterworth filter, a Chebyshev filter, an Elliptic filter, a Bessel filter, a Gaussian filter, an Optimum “L” (Legendre) filter, a Linkwitz-Riley filter, etc. In some implementations, signal processing component 414 can convert, into acceleration data, the raw signal obtained from vibration detecting sensor 410 or the processed signal obtained from signal processing component 414. Acceleration data can indicate the acceleration (the rate of change of the velocity) of the monitoring system 129 (or the vibration detecting sensor 410) in its own instantaneous rest frame. In some implementations, signal processing component 414 can convert the raw (or processed) signal into a digital signal. In some implementations, application 112 can process the raw signal, convert the raw or processed signal into acceleration data, etc.

Wired communication device 416 can include any wired connector configured to transmit data (e.g., the raw signal, the processed signal, acceleration data, etc.) between monitoring system 129 and a computer system or component of operating environment 100 (e.g., client device 110, network 130, data store 140, etc.) or any other external computer system (not shown), such as an external server. In some implementations, wired communication device 416 can include an international electrotechnical commission (IEC) metric screw sized connector (e.g., a circular connector), an Ethernet connector, a coaxial connector, a fiber optic connector, etc. An IEC metric screw sized connector (e.g., a M5 connector, a M8 connector, a M12 connector, etc.) can include any multipin connector. In some implementations, wired communication device 416 can include a Japan Solderless Terminal (JST) connector. In other implementations, other types of connectors can be used. In some implementations, wired communications device 416 (e.g., a IEC metric screw sized connector, a JST connector, etc.) can provide multiple different functions, such as both power and data transmission. Accordingly, certain devices and components of monitoring system 129 can be combined into a single component (e.g., wired communications device 416 and power component 412 can be combined into a single device).

Wireless communication device 418 can be any device configured to provide monitoring system 129 with remote (wireless) communication capabilities. In particular, wireless communication device 418 can be configured to wirelessly transmit data (e.g., the raw signal, the processed signal, acceleration data, etc.) between monitoring system 129 and another computer system or component of operating environment 100 (e.g., client device 110, network 130, data store 140, etc.) or any other external computer system (not shown), such as an external server. In some implementations, wireless communication device 418 can include a Bluetooth device, a WiFi device, a long-term evolution (LTE) device, etc. For example, the wireless communication device 418 can establish a wireless connection with the client device 110 and transmit data generated by the vibration detecting sensor 410 to the computer system via the wireless connection.

In some implementations, monitoring system 129 can include a body (e.g., a housing) configured to contain and/or be coupled to one or more of vibration detecting sensor 410, power component 412, signal processing component 414, wired communication device 416, and/or wireless communication device 418. The body can be of any suitable shape or design (e.g., rectangular, cubical, trapezoidal, ellipsoidal, etc.). The body can be compact in size, such as, having the physical dimensions (e.g., the length, width, and/or height) of each side between 5 and 20 millimeters (mm). In other implementations, one or more physical dimensions can be greater than 20 mm. The dimensions of the body can correspond to the size of the one or more of vibration detecting sensor 410, power component 412, signal processing component 414, wired communication device 416, wireless communication device 418. For example, a monitoring system 129 that includes a vibration sensor having a base of approximately 100 mm² can be of a volume less than 200 mm³.

The body can include one or more surfaces configured to couple to a particularly shaped surface, such as, for example, a surface of metrology equipment 128. For example, the one or more body surfaces (such as, for example, the base of the body) can be a flat surface, a concave surface, a convex surface, or any other shaped surface to enable monitoring system 129 to be coupled to a particular surface of metrology equipment 128 (e.g., a flat surface, a cylindrical surface, etc.).

In some implementations, one or more of vibration detecting sensor 410, power component 412, signal processing component 414, wired communication device 416, and/or wireless communication device 418 can be coupled to a medium used to connect electronic components, such as, for example, a PCB, a heated bed, etc. The medium can be rigid or flexible. In some implementations, the medium can be configured to mount to the metrology equipment. For example, the medium can be configured to be the base of monitoring system 129. In some implementations, a flexible medium can be configured to couple to a base of monitoring system 129 (or act as the base of monitoring system 129) such that the medium and the base both exhibit a similar shape (e.g., are similarly concave, are similarly convex, etc.). This can allow the monitoring system to couple to other than flat surfaces of metrology equipment 128, such as those having a convex or concave shape.

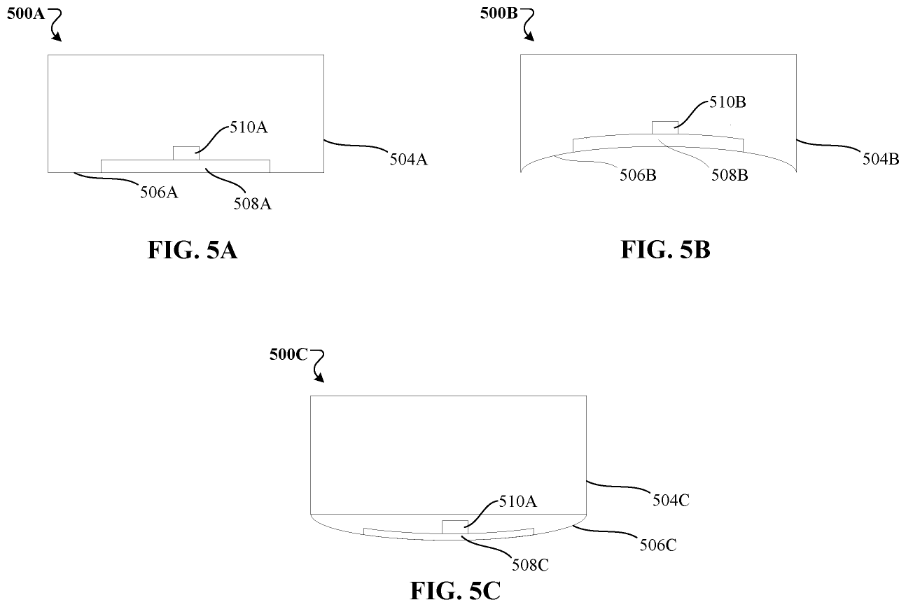

FIGS. 5A-5C depict respective side views of different example shapes of the base of a monitoring system. In particular, FIG. 5A shows a side view of monitoring system 500A, which include body 504A and base 506A. Base 506A is a flat base. FIG. 5B shows a side view of monitoring system 500B, which include body 504B and base 506B. Base 506B is a concave base. FIG. 5C shows a side view of monitoring system 500C, which include body 504C and base 506C. Base 506C is a convex base.

In certain implementations, one or more sections of the body (e.g., 504A-504C) base 506A-506C can be fabricated from a metal (e.g., steel, titanium, sheet metal, aluminum, etc.), a plastic, (e.g., Polyvinyl Chloride (PVC), acrylic fibers, etc.), wood, glass, or any other suitable material. In some implementations, base 506A-506C can be fabricated from a lightweight, versatile and/or durable material(s). In certain implementations, the weight and size (physical dimensions) of the body can be configured to increase or maintain the resonance frequency of monitoring unit 129 (or prevent noticeably change that can affect the data obtained from the vibration detecting sensor 410). As such, an increased resonance frequency of the monitoring unit 129 may not affect (or reduce affecting) the natural frequency of vibration detecting sensor 410, thus reducing or removing errors in measurement readings produced by vibration detecting sensor 410.

In some implementations, vibration detecting sensor 410 can be coupled to a rigid or flexible medium used to connect electronic components, such as, for example, a printed circuit board, a heated bed, etc. As discussed above, a flexible medium can be configured to couple to the base of monitoring system 129 such that the medium and the base both exhibit a similar shape (e.g., are similarly concave, are similarly convex, etc.). In particular, FIG. 5A further includes medium 508A coupled to vibration detecting sensor 510A. Medium 508A has a flat shape and is coupled to base 506A, which has a similar flat shape. FIG. 5B further includes medium 508B coupled to vibration detecting sensor 510B. Medium 508B has a concave shape and is coupled to base 506B, which has a similar concave shape. FIG. 5C further includes medium 508C coupled to vibration detecting sensor 510C. Medium 508C has a convex shape and is coupled to base 506C, which has a similar convex shape.

Returning to FIG. 1, client device 110 can include a computing device such as personal computers (PCs), laptops, mobile phones, smart phones, tablet computers, netbook computers, network connected televisions (“smart TVs”), network-connected media players (e.g., Blu-ray player), a set-top box, over-the-top (OTT) streaming devices, operator boxes, etc. Each client device 110 can include an operating system that allows users to one or more of generate, view, or edit data (e.g., indication associated with manufacturing equipment 124, data receive from monitoring system 129, corrective actions associated with manufacturing equipment 124, etc.).

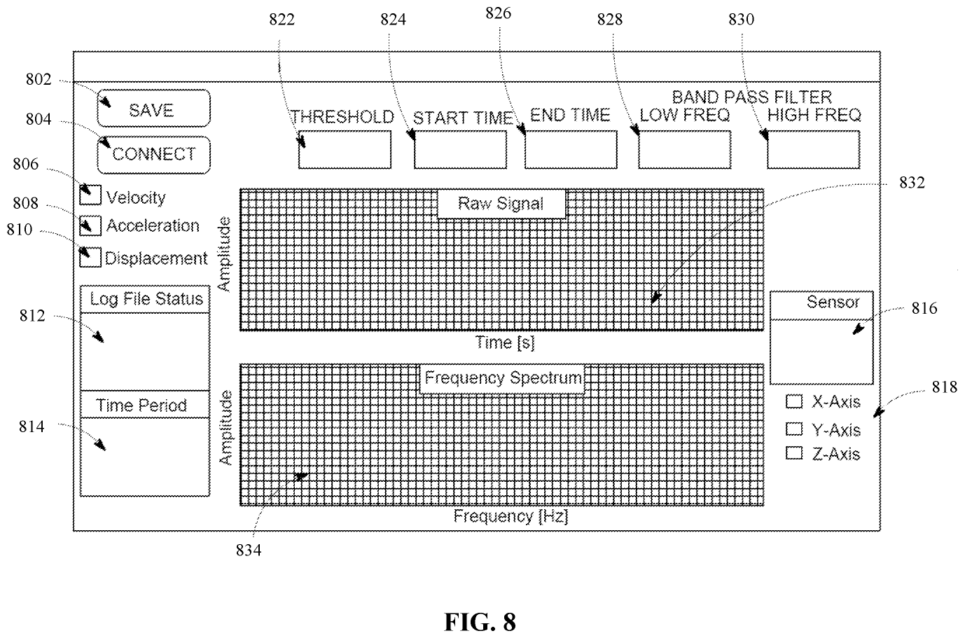

Client device 110 can include application 112, user interface (UI) 114, fault determination component 116, and corrective action component 118. Application 112 can be a mobile application, a desktop application, a web browser, etc. In some implementations, application 112 can present, on a display device of client device 110, a user interface (UI) (e.g., UI 114) to receive user input associated with obtaining data from monitoring system 129, converting or modifying data obtained from monitoring system 129 (e.g., filtering data, converting acceleration data to velocity data or displacement data, etc.), outputting data, selecting a corrective action, etc. Data generated by UI component can be referred to as vibration data, and can include filtered data, acceleration data, displacement data, velocity data, other related data, or any combination thereof. Data received and processed by application 112 can be provide for display on UI component 114 in real-time, near real-time, or as historical data related to vibrations or shock experienced by monitoring system 129. UI component 114 will be discussed in detail in FIG. 8 below.

The vibration data can be provided to fault determination component 116. Fault determination component 116 can determine whether a vibration measured by monitoring system 129 was sufficient to disturb a process of a metrology equipment 128. Fault determination component 116 can determine whether vibration disturbed a process based on an amplitude of vibration, one or more amplitudes at various frequencies, or the like. Fault determination component 116 can determine vibrational disturbance based on whether a vibration satisfies a threshold condition, e.g., whether one or more amplitudes of vibration meet a threshold value.

Data from fault determination component 116 can be provided to corrective action component 118. Corrective action component 116 can recommend one or more corrective actions based on data received from fault determination component 116. Corrective action component 118 can perform one or more corrective actions based on data received from fault determination component 116. Corrective actions associated with corrective action component 118 may include flagging a measurement performed. Flagging the measurement can include providing metadata that indicates the measurement is unreliable. Flagging the measurement can be performed in situations where vibration occurs during a metrology measurement that may interfere with the measurement. Flagging the measurement can be performed in situations where an optical, infrared, or other radiation detection measurement is performed. Flagging the measurement can be performed in situations where a position of the substrate is measured, such as a notch detection operation.

In some implementations, corrective actions associated with corrective action component 118 can include causing a measurement to be repeated. For example, a metrology measurement performed in a vibrating chamber can be repeated soon after it is performed. A metrology measurement can be repeated to improve reliability of a measurement taken during vibration of the chamber.

In some implementation, corrective actions can include adjusting operation of a mechanical component of a substrate processing system. For example, a pump, actuator, or other moving part may be causing vibration of the chamber that may interfere with an operation performed in the chamber. Operation of the mechanical component can be adjusted, slowed, stopped, or the like, to enable an operation to be performed in the chamber more reliably.

In some implementations, corrective actions can include recommending maintenance. Mechanical components of a manufacturing system such as pumps may induce vibration as they age or fail. A vibration signature based on position error data of a motor may be utilized in recommending maintenance on one or more components of a substrate processing system.

In some implementations, corrective actions can include providing one or more alerts to a user. Alerts may include indications associated with corrective actions, processing tool drift, aging, or failure, component drift, aging, or failure, external sources of vibration to be addressed, statistics of historical vibration, etc. The corrective actions can be stored in a library on data store 140.

Data store 140 can be a memory (e.g., random access memory), a drive (e.g., a hard drive, a flash drive), a database system, or another type of component or device capable of storing data. Data store 140 can include multiple storage components (e.g., multiple drives or multiple databases) that can span multiple computing devices (e.g., multiple server computers). The data store 140 can store data associated with processing a substrate at manufacturing equipment 124. For example, data store 140 can store data collected by sensors 126 at manufacturing equipment 124 before, during, or after a substrate process (referred to as process data). Process data can refer to historical process data (e.g., process data generated for a prior substrate processed at the manufacturing system) and/or current process data (e.g., process data generated for a current substrate processed at the manufacturing system). Data store can also store spectral data or non-spectral data associated with a portion of a substrate processed at manufacturing equipment 124. Spectral data can include historical spectral data and/or current spectral data.

Data store 140 can also store contextual data associated with one or more substrates processed at the manufacturing system. Contextual data can include a recipe name, recipe step number, preventive maintenance indicator, operator, etc. Contextual data can refer to historical contextual data (e.g., contextual data associated with a prior process performed for a prior substrate) and/or current process data (e.g., contextual data associated with current process or a future process to be performed for a prior substrate). The contextual data can further include identify sensors that are associated with a particular sub-system of a process chamber.

Data store 140 can also store task data. Task data can include one or more sets of operations to be performed for the substrate during a deposition process and can include one or more settings associated with each operation. For example, task data for a deposition process can include a temperature setting for a process chamber, a pressure setting for a process chamber, a flow rate setting for a precursor for a material of a film deposited on a substrate, etc. In another example, task data can include controlling pressure at a defined pressure point for the flow value. Task data can refer to historical task data (e.g., task data associated with a prior process performed for a prior substrate) and/or current task data (e.g., task data associated with current process or a future process to be performed for a substrate).

In some implementations, data store 140 can be configured to store data that is not accessible to a user of the manufacturing system. For example, process data, spectral data, contextual data, etc. obtained for a substrate being processed at the manufacturing system is not accessible to a user (e.g., an operator) of the manufacturing system. In some implementations, all data stored at data store 140 can be inaccessible by the user of the manufacturing system. In other or similar implementations, a portion of data stored at data store 140 can be inaccessible by the user while another portion of data stored at data store 140 can be accessible by the user. In some implementations, one or more portions of data stored at data store 140 can be encrypted using an encryption mechanism that is unknown to the user (e.g., data is encrypted using a private encryption key). In other or similar implementations, data store 140 can include multiple data stores where data that is inaccessible to the user is stored in one or more first data stores and data that is accessible to the user is stored in one or more second data stores.

The client device 110, manufacturing equipment 124, and data store 140 can be coupled to each other via a network 130. In some implementations, network 130 is a public network that provides client device 110 with access to data store 140, manufacturing equipment 124 and other publicly available computing devices. In some implementations, network 130 is a private network that provides client device 110 access to manufacturing equipment 124, data store 140, and other privately available computing devices. Network 130 can include one or more wide area networks (WANs), local area networks (LANs), wired networks (e.g., Ethernet network), wireless networks (e.g., an 802.11 network or a Wi-Fi network), cellular networks (e.g., a Long-Term Evolution (LTE) network), routers, hubs, switches, server computers, cloud computing networks, and/or a combination thereof.

In implementations, a “user” can be represented as a single individual. However, other implementations of the disclosure encompass a “user” being an entity controlled by a plurality of users and/or an automated source. For example, a set of individual users federated as a group of administrators can be considered a “user.”

FIG. 2 is a top schematic view of an example manufacturing system 200, according to aspects of the present disclosure. Manufacturing system 200 can perform one or more processes on a substrate 202. Substrate 202 can be any suitably rigid, fixed-dimension, planar article, such as, e.g., a silicon-containing disc or wafer, a patterned wafer, a glass plate, or the like, suitable for fabricating electronic devices or circuit components thereon.

Manufacturing system 200 can include a process tool 204 and a factory interface 206 coupled to process tool 204. Process tool 204 can include a housing 208 having a transfer chamber 210 therein. Transfer chamber 210 can include one or more process chambers (also referred to as processing chambers) 214, 216, 218 disposed therearound and coupled thereto. Process chambers 214, 216, 218 can be coupled to transfer chamber 210 through respective ports, such as slit valves or the like. Transfer chamber 210 can also include a transfer chamber robot 212 configured to transfer substrate 202 between process chambers 214, 216, 218, load lock 220, etc. Transfer chamber robot 212 can include one or multiple arms where each arm includes one or more end effectors at the end of each arm. The end effector can be configured to handle particular objects, such as wafers, sensor discs, sensor tools, etc.

Process chambers 214, 216, 218 can be adapted to carry out any number of processes on substrates 202. A same or different substrate process can take place in each processing chamber 214, 216, 218. A substrate process can include atomic layer deposition (ALD), physical vapor deposition (PVD), chemical vapor deposition (CVD), etching, annealing, curing, pre-cleaning, metal or metal oxide removal, or the like. Other processes can be carried out on substrates therein. Process chambers 214, 216, 218 can each include one or more sensors configured to capture data for substrate 202 before, after, or during a substrate process. For example, the one or more sensors can be configured to capture spectral data and/or non-spectral data for a portion of substrate 202 during a substrate process. In other or similar implementations, the one or more sensors can be configured to capture data associated with the environment within process chamber 214, 216, 218 before, after, or during the substrate process. For example, the one or more sensors can be configured to capture data associated with a temperature, a pressure, a gas concentration, etc. of the environment within process chamber 214, 216, 218 during the substrate process.

In some implementations, metrology equipment (not shown) can be located within the process tool. In other implementations, metrology equipment (not shown) can be located within one or more process chambers 214, 216, 218. In some implementations, the substrate can be placed onto metrology equipment using transfer chamber robot 212. In other implementations, the metrology equipment can be part of the substrate support assembly (not shown). Metrology equipment can provide metrology data associated with substrates processed by manufacturing equipment 124. The metrology data can include a value of film property data (e.g., wafer spatial film properties), dimensions (e.g., thickness, height, etc.), dielectric constant, dopant concentration, density, defects, etc. In some implementations, the metrology data can further include a value of one or more surface profile property data (e.g., an etch rate, an etch rate uniformity, a critical dimension of one or more features included on a surface of the substrate, a critical dimension uniformity across the surface of the substrate, an edge placement error, etc.). The metrology data can be of a finished or semi-finished product. The metrology data can be different for each substrate. Metrology data can be generated using, for example, reflectometry techniques, ellipsometry techniques, TEM techniques, and so forth.

A load lock 220 can also be coupled to housing 208 and transfer chamber 210. Load lock 220 can be configured to interface with, and be coupled to, transfer chamber 210 on one side and factory interface 206. Load lock 220 can have an environmentally-controlled atmosphere that can be changed from a vacuum environment (wherein substrates can be transferred to and from transfer chamber 210) to an at or near atmospheric-pressure inert-gas environment (wherein substrates can be transferred to and from factory interface 206) in some implementations. Factory interface 206 can be any suitable enclosure, such as, e.g., an Equipment Front End Module (EFEM). Factory interface 206 can be configured to receive substrates 202 from substrate carriers 222 (e.g., Front Opening Unified Pods (FOUPs)) docked at various load ports 224 of factory interface 206. A factory interface robot 226 (shown dotted) can be configured to transfer substrates 202 between carriers (also referred to as containers) 222 and load lock 220. Carriers 222 can be a substrate storage carrier or a replacement part storage carrier.

Manufacturing system 200 can also be connected to a client device (e.g., client device 110, not shown) that is configured to provide information regarding manufacturing system 200 to a user (e.g., an operator). In some implementations, the client device can provide information to a user of manufacturing system 200 via one or more graphical user interfaces (GUIs). For example, the client device can provide information regarding a target thickness profile for a film to be deposited on a surface of a substrate 202 during a deposition process performed at a process chamber 214, 216, 218 via a GUI. The client device can also provide information regarding anomaly detection and fault classification, in accordance with implementations described herein.

As shown, transfer chamber 210 can include metrology equipment 128 and monitoring system 129. In other implementations (not shown), metrology equipment 128 and/or monitoring system 129 can be part of and/or coupled to process chambers 214, 216, 218, factory interface 206, or any other component of manufacturing system 200.

Manufacturing system 200 can also include a system controller 228. System controller 228 can be and/or include a computing device such as a personal computer, a server computer, a programmable logic controller (PLC), a microcontroller, and so on. System controller 228 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 228 can include a data storage device (e.g., one or more disk drives and/or solid-state drives), a main memory, a static memory, a network interface, and/or other components. System controller 228 can execute instructions to perform any one or more of the methodologies and/or implementations described herein. In some implementations, system controller 228 can execute instructions to perform one or more operations at manufacturing system 200 in accordance with a process recipe. The instructions can be stored on a computer readable storage medium, which can include the main memory, static memory, secondary storage and/or processing device (during execution of the instructions).

System controller 228 can receive data from sensors (e.g., sensors 126, now shown) included on or within various portions of manufacturing system 200 (e.g., processing chambers 214, 216, 218, transfer chamber 210, load lock 220, etc.). In some implementations, data received by the system controller 228 can include spectral data and/or non-spectral data for a portion of substrate 202. In other or similar implementations, data received by the system controller 228 can include data associated with processing substrate 202 at processing chamber 214, 216, 218, as described previously. For purposes of the present description, system controller 228 is described as receiving data from sensors included within process chambers 214, 216, 218. However, system controller 228 can receive data from any portion of manufacturing system 200 and can use data received from the portion in accordance with implementations described herein. In an illustrative example, system controller 228 can receive data from one or more sensors for process chamber 214, 216, 218 before, after, or during a substrate process at the process chamber 214, 216, 218. Data received from sensors of the various portions of manufacturing system 200 can be stored in a data store 250. Data store 250 can be included as a component within system controller 228 or can be a separate component from system controller 228. In some implementations, data store 250 can be data store 140 described with respect to FIG. 1.

FIG. 3 depicts a metrology system 300 of a substrate manufacturing system, according to some embodiments. Metrology system 300 can be similar to or the same as metrology equipment 128. Metrology system 300 can be included in a process chamber, such as one of the chambers 214, 216, 218 of FIG. 2, in a transfer chamber, etc. Metrology system 300 includes metrology device 302. The metrology device 302 can be or include a probe for measuring or monitoring one or more properties of substrate 306. Metrology device 302 can be associated with a field of view 304. Metrology device 302 can include one or more sensors of electromagnetic radiation. Metrology device 302 can include one or more of optical sensors, IR sensors, etc. Metrology device 302 can measure one or more properties of a substrate 306. Metrology device 302 can include a device for measuring substrate thickness, optical properties, material properties, electrical properties, etc. Metrology device 302 can include a reflectometry device. Metrology device 302 can be or include an interferometer device. Metrology device 302 can further be coupled to a spectrometer, an analyzer, a computer or processing device, etc.

Metrology device 302 can be any device that benefits from a still, static, or vibration free environment, such as a tool for measuring the placement of a substrate, etc. One or more measurement operations can be impacted by vibration of substrate 306 relative to metrology device 302. For example, measurements can be taken by averaging a signal received by metrology device 302 over some duration of time. Motion of the substrate within that duration can cause metrology device 302 to generate data that is less accurate, less reliable, less applicable, or the like, than if the system remained still, without vibration of substrate 306. Vibration can be caused by components of the manufacturing system (e.g., moving parts of the system causing vibration), components associated with the manufacturing system (e.g., off-tool pumps, motors, or other parts), outside interferences (e.g., a user bumping into a tool), or the like.

Metrology system 300 further includes substrate support 308. Substrate support 308 can include stage 310 and pedestal 312. Substrate support 308 can include a device for holding a substrate, such as a vacuum chuck, electrostatic chuck, mechanical chuck, magnetic chuck, or the like. Substrate support 308 can include a plate or other surface with a substrate-shaped pocket or a set of pins surrounding a substrate placement zone for securing a substrate position on the substrate support 308. Metrology system 300 further includes stage motor 314. Stage motor 314 is utilized in repositioning substrate 306. Stage motor 314 can be coupled to (e.g., travel with) substrate support 308, stage motor 314 can remain stationery and drive substrate support 308, etc.

In some embodiments, substrate support 308 can be configured to be moved in multiple dimensions. Substrate support 308 can include a number of stage motors (e.g., actuators) that are configured to move substrate support 308. Through this disclosure, the word “motor” is used for describing means for performing substrate relocation, though methods of the disclosure can be applicable to other means of relocating a substrate. Substrate support 308 can adjust a position of substrate 306 in order to bring a target portion of substrate 306 into field of view 304 of metrology device 302. Substrate support 308 can adjust a position of substrate 306 in order to make measurements at multiple locations of substrate 306, e.g., spread around the surface of substrate 306. In some embodiments, each motor can be configured to generate one dimension of motion. For example, a first motor can generate motion of substrate support 308 in an “x” dimension, and a second motor can generate motion of the substrate support 308 in a “y” dimension. In another example, a first motor can generate motion of substrate support 308 in a first linear dimension, and a second motor can generate rotation motion of substrate support 308. A first actuator can be a linear actuator, and a second actuator can be a rotational actuator.

Metrology system 300 can be included in a metrology chamber. Metrology system 300 can be part of a metrology chamber that is coupled to a substrate processing tool. Metrology system 300 can be part of an integrated metrology system. Metrology system 300 can be part of a chamber that is not a dedicated metrology chamber, e.g., a transfer chamber, a process chamber, etc. Metrology system 300 can be part of an in-situ metrology system.

Metrology system 300 can include monitoring system 320. Monitoring system 320 can be similar to or the same monitoring system 129 and can measure vibrations experience by metrology system 300 or any component of metrology system 300. For example, as illustrated, monitoring system 320 can be coupled to metrology device 302. In other implementations, monitoring component can be coupled to the outside of metrology system 300.

Pumps, actuators, valves, motors, or the like can generate additional vibrations as they age, become damaged, begin failing, or the like. Mechanical components causing vibration can be slowed, shut off, have timing or operations adjusted to reduce vibrations, etc. By mitigating negative effects of vibrations of aging components, service lifetimes of mechanical components can be extended, as a need to replace components initiating vibration can be mitigated by vibration monitoring systems.

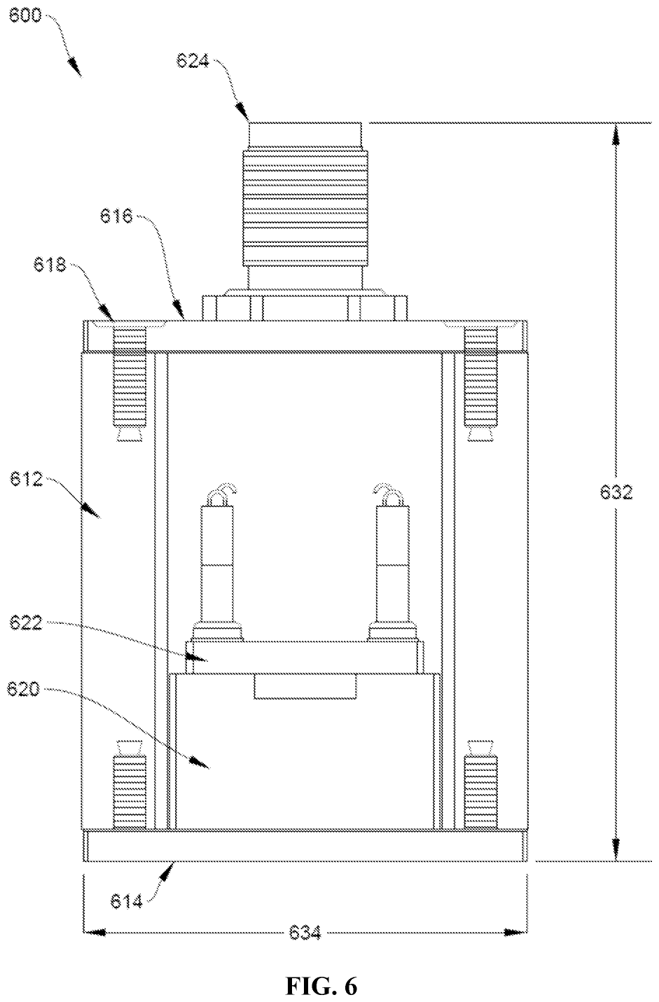

FIG. 6 depicts an example monitoring system 600, in accordance with some implementations of the present disclosure. In some implementations, monitoring system 600 includes a body (e.g., a housing) (which includes base 614, side enclosure 612, and top 616), medium 620, accelerometer 622, and connector 624. Monitoring system 600 can be similar to or the same as monitoring system 129. In some implementations, monitoring system 129 can be coupled to metrology equipment 128.

The housing can be rectangular or cubical housing structure and can include base 614, side enclosure 612, and top 616. Base 614 and top 616 can each be connected to side enclosure 612 using one or more screws 618 (e.g., machine screw, hex screw, flat head screw, Allen head screws, etc.), bolts, nails, an adhesive, an epoxy, magnets, etc. Base 614, top 616, and enclosure 612 can each be fabricated from a metal (e.g., steel, titanium, sheet metal, aluminum, etc.), a plastic, (e.g., Polyvinyl Chloride (PVC), acrylic fibers, etc.), wood, glass, or any other suitable material. In some implementations, a lightweight, versatile and/or durable material(s) can be desirable for base 614, top 616, and enclosure 612. In some implementations, enclosure 612 can be made from a transparent material, such as acrylic. In some implementation, enclosure 612 can include two or more separate parts (e.g., four coupled walls). In some implementations, any combination of base 614, side enclosure 612, and top 616 can be a single component. In an implementation, the length of each side 634 of base 614 can be approximately 5 mm-60 mm, and the vertical length (e.g., height) 632 of base 614 can be approximately 20-60 mm. In other implementations, the base length (and width if the base is rectangular) and height can each be a particular dimension due to the materials used.

Medium 620 can be coupled to base 614. In some implementations, medium 614 can provide act as a heat sink for accelerometer 622. In particular, bed 614 can transfer heat from accelerometer 622 to medium 614. In some implementations, medium 620 can act as a buffer between accelerometer 622 and base 614. In other implementations, medium 620 can be removed from monitoring system 600, and accelerometer 622 can be directly coupled to base 614.

Accelerometer 622 can measure the acceleration (rate of change of velocity) of monitoring system 600 and/or metrology equipment 128. Accelerometer 622 can generate accelerometer data, which can include time trace data associated with vibration of monitoring system 600 and/or metrology equipment 128. In some implementations, accelerometer 622 can include a signal processing component for filtering and converting the raw signal captured by the accelerometer into accelerometer data. It is noted that accelerometer 622 is used by way of illustrative example, and that other vibration detecting device can be used instead.

Top 616 can be coupled to connector 624. Connector 624 can be a wired connector configured to provide power to monitoring system 600 and/or transmit data to and/or from accelerometer 622. In some implementations, connector 624 can be an IEC M12 connector. In some implementations, monitoring system 600 can include a wireless communication device (not shown), such as a Bluetooth device, a WiFi device, a long-term evolution (LTE) device, etc.

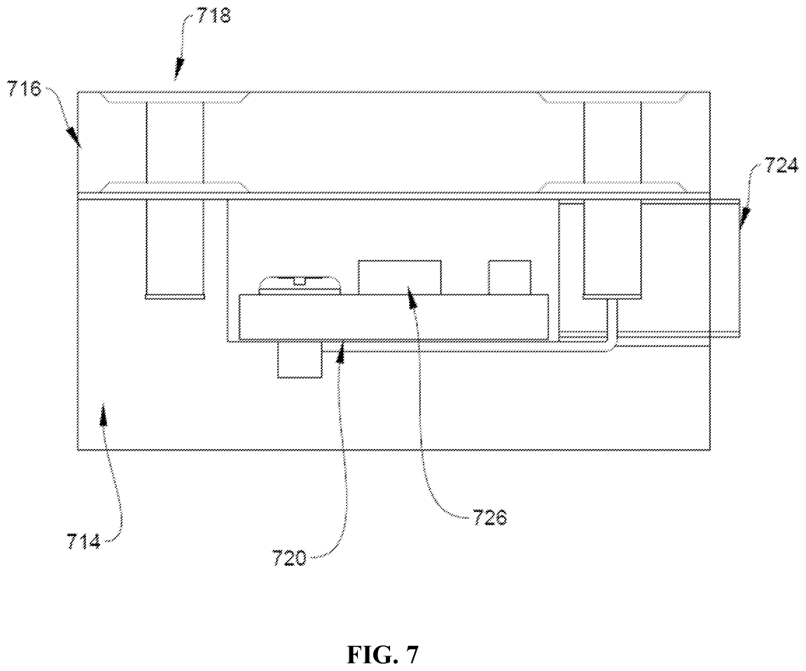

FIG. 7 depicts another example monitoring system 700, in accordance with some implementations of the present disclosure. In some implementations, monitoring system 700 includes base 710, top 716, medium 720, connector 724, electrical component 726. Monitoring system 700 can be similar to or the same as monitoring system 129. In some implementations, monitoring system 129 can be coupled to metrology equipment 128.

Base 710 and top 716 can form a housing for medium 720, connector 724, electrical component 726. Top 716 can be connected to base 710 using one or more screws 718 (e.g., machine screw, hex screw, flat head screw, Allen head screws, etc.), bolts, nails, an adhesive, an epoxy, magnets, etc. Base 710 and top 716 can each be fabricated from a metal (e.g., steel, titanium, sheet metal, aluminum, etc.), a plastic, (e.g., Polyvinyl Chloride (PVC), acrylic fibers, etc.), wood, glass, or any other suitable material. Similar to monitoring system 600, a lightweight, versatile and/or durable material(s) can be desirable for base 710 and top 716. The length of each side of base 710 can be approximately between 5 mm-20 mm. The vertical length (e.g., height) of the housing (e.g., base 710 and top 716) can also be between approximately between 5-20 mm. In other implementations, the housing length, width, and height can each be a particular dimension due to the materials used.

Medium 720 can be a rigid or flexible printed circuit board, a heated bed, etc. medium 720 can be coupled to one or more electrical component 726, such as, for example, a vibration detecting sensor (e.g., vibration detecting sensor 410), a power component (e.g., power component 412), a signal processing component (e.g., signal processing component 414), a wireless communication device (e.g., wireless communication device 418), and/or a wired communication device (e.g., connector 724). Connector 724 can be a JST connector and can provide multiple both power and data transmission to monitoring system 700.

FIG. 8 illustrates an example UI 800 of an application displayed on client device 110, in accordance with some implementations of the present disclosure. The UI 800 can be generated by application 112 of client device 110 of FIG. 1 (or by a remote server) for presentation on client device 110. Accordingly, the UI 800 can be generated by one or more processing devices of the client device 110 of FIG. 1. As illustrated, UI 800 provides, for presentation to the user, an interface that include buttons 802, 804, display parameters 806, 808, 810, log file status window 812, time period window 814, sensor window 816, axis parameters 818, threshold window 822, start time window 824, end time window 826, band pass filter windows 828, 830, raw signal display 832, and frequency spectrum display 834.

Buttons 802, 804 can include save button 802 and connect button 804. Save button 802 can save a configuration of the UI (e.g., which parameters and values are selected). Connect button 804 can connect the UI to a particular monitoring system 129. For example, selecting the connect button 804 can cause a sub-window to be presented on UI 800 that list the available monitoring system to connect to. Selection of a monitoring system can cause the UI 800 to retrieve data from the selected monitoring system.

Display parameters 806, 808, and 810 can enable selection of the type of data to display on raw signal display 832 and/or frequency spectrum display 834. In particular, velocity parameter 806 can display the velocity data associated with the monitoring system, acceleration parameter 808 can display the acceleration data associated with the monitoring system, and displacement parameter 810 can display the displacement data associated with the monitoring system. Displacement data and velocity data can be determined from the acceleration data using, for example, integral functions. In some implementations, application 112 can apply a Fast Fourier transform (FFT) to transform data from the time domain into the frequency domain. In particular, the raw signal data can be converted, using FFT, into a graph showing the frequencies of the vibrations that affect the metrology equipment.

Log file status 812 can display data related to usage patterns, activities, and operations associated with UI 800 and/or monitoring system 129. Time period window 814 can display data related to a time-period related to the acceleration data, the display data, etc. Sensor window 816 can display data related to the selected monitoring system (e.g., name, identifier, location in the manufacturing system, etc. Axis parameters 818 can enable selection of which along which access the vibrations occurred. For example, selecting the x-axis button can display on raw signal display 832 and/or frequency spectrum display 834 data related to movement in the x-direction.

Threshold window 822 can enable selection of one or more threshold values (e.g., amplitude) for display, a corrective action, etc. For example, a value input into threshold window 822 can trigger a corrective action, can trigger an alert or highlight illustrating corresponding amplitude on raw signal display 832 and/or frequency spectrum display 834, etc.

Start time window 824 can enable selection of a start time for the data displayed on raw signal display 832 and/or frequency spectrum display 834. End time window 826 can enable selection of an end time for data displayed on raw signal display 832 and/or frequency spectrum display 834. Band pass filter windows 828, 830 can enable selection low pass frequency filter 828 and a high pass frequency filter 830. A low pass frequency filter can pass signals below its cutoff frequency while attenuating all signals above it. A high pass frequency filter can pass signals above its cutoff frequency while attenuating all signals below it.

Raw signal display 832 can display a raw acceleration signal obtained from monitoring system 832. In some implementations, the raw signal can be filtered using, for example, band pass filters, converted into raw displacement and/or velocity data, etc. Frequency spectrum display 834 can display the range of frequencies contained by a raw, processed, filtered, or converted signal. It is noted that UI 800 is used for illustrative purposed, and different display configurations can be used.

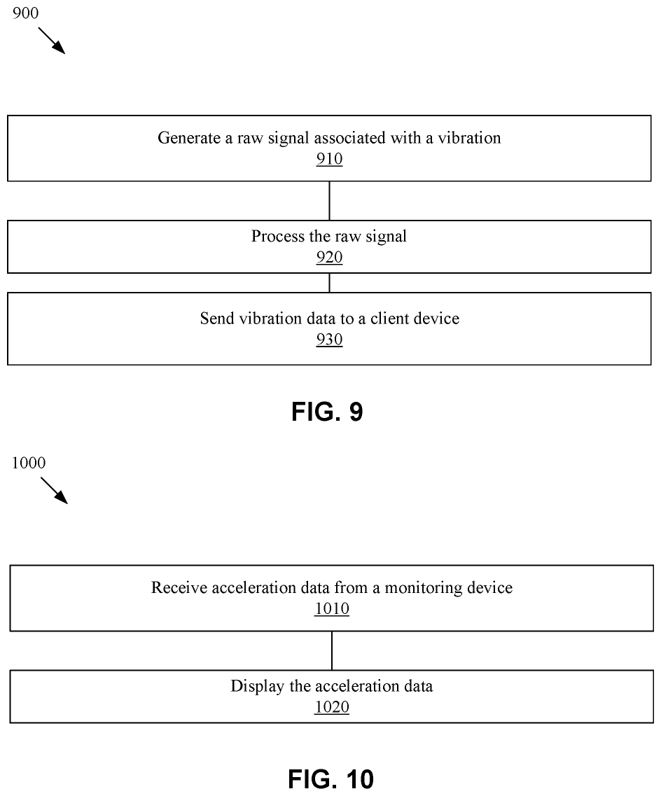

FIG. 9 is a flow chart of a method 900 for generating and sending vibration data, according to aspects of the present disclosure. Method 900 is performed by processing logic that can include hardware (circuitry, dedicated logic, etc.), software (such as is run on a general-purpose computer system or a dedicated machine), firmware, or some combination thereof. In one implementation, method 900 can be performed by a computer system, such as operating environment 100 of FIG. 1. In other or similar implementations, one or more operations of method 900 can be performed by one or more other machines not depicted in the figures. In some aspects, one or more operations of method 900 can be performed by monitoring system 129.

At operation 910, processing logic generates a raw signal associated with a vibration. The raw signal can be related to a vibration experience by a monitoring system coupled to metrology equipment.

At operation 920, processing logic processes the raw signal. For example, the processing logic can apply a filter to the raw signal, convert the raw signal into acceleration data, etc.

At operation 930, processing logic send vibration data to a client device. The vibration data can include the raw signal and/or processed signal.

FIG. 10 is a flow chart of a method 1000 for displaying vibration data by a client device, according to aspects of the present disclosure. Method 1000 is performed by processing logic that can include hardware (circuitry, dedicated logic, etc.), software (such as is run on a general-purpose computer system or a dedicated machine), firmware, or some combination thereof. In one implementation, method 1000 can be performed by a computer system, such as operating environment 100 of FIG. 1. In other or similar implementations, one or more operations of method 1000 can be performed by one or more other machines not depicted in the figures. In some aspects, one or more operations of method 700 can be performed by client device 110.

At operation 1010, processing logic receives acceleration data from a monitoring system.

At operation 1020, processing logic displays the acceleration data. For example, processing logic can display the acceleration data on a UI associated with an application presented on the client device. In response to user input, the processing logic can modify the displayed data. For example, in response to receiving user input to display displacement or velocity data, the processing logic can convert the acceleration data to displacement or velocity data, and display the displacement or velocity data. In another example, in response to user input selecting a filter (e.g., a low pass frequency filter, a high pass frequency filter, etc.), the processing logic can apply a filter to the acceleration data.

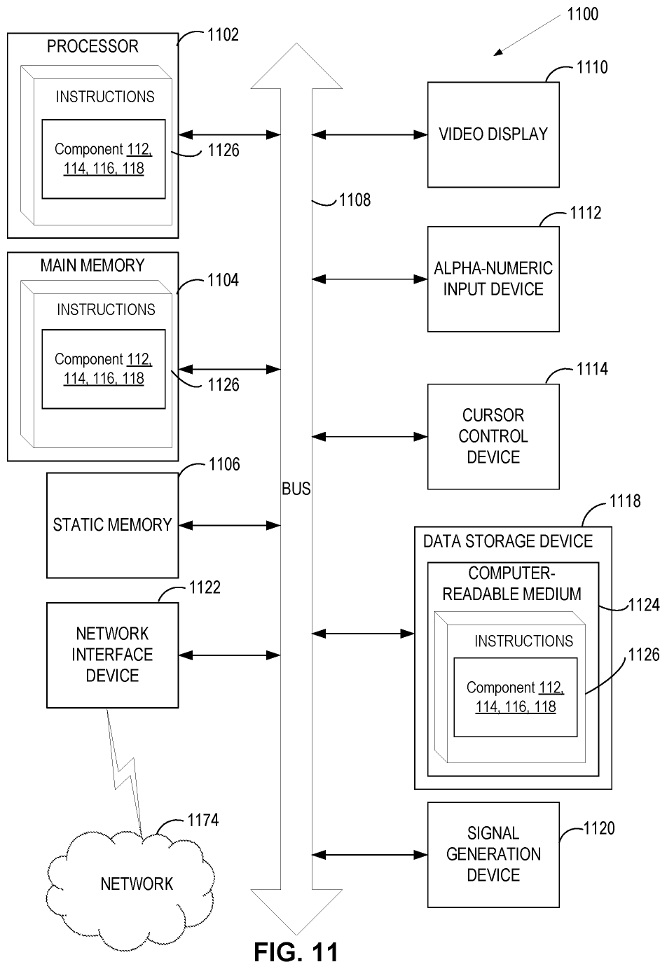

FIG. 11 is a block diagram illustrating a computer system 1100, according to certain implementations. In some implementations, computer system 1100 can be connected (e.g., via a network, such as a Local Area Network (LAN), an intranet, an extranet, or the Internet) to other computer systems. Computer system 1100 can operate in the capacity of a server or a client computer in a client-server environment, or as a peer computer in a peer-to-peer or distributed network environment. Computer system 1100 can be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 1100 can include a processing device 1102, a volatile memory 1104 (e.g., Random Access Memory (RAM)), a non-volatile memory 1106 (e.g., Read-Only Memory (ROM) or Electrically-Erasable Programmable ROM (EEPROM)), and a data storage device 1116, which can communicate with each other via a bus 1108.

Processing device 1102 can be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 1100 can further include a network interface device 1122 (e.g., coupled to network 1174). Computer system 1100 also can include a video display unit 1110 (e.g., an LCD), an alphanumeric input device 1112 (e.g., a keyboard), a cursor control device 1114 (e.g., a mouse), and a signal generation device 1120.

In some implementations, data storage device 1116 can include a non-transitory computer-readable storage medium 1124 on which can store instructions 1126 encoding any one or more of the methods or functions described herein, including instructions encoding components of FIG. 1 (e.g., components 112, 114, 116, 118, etc.) and for implementing methods described herein.

Instructions 1126 can also reside, completely or partially, within volatile memory 1104 and/or within processing device 1102 during execution thereof by computer system 1100, hence, volatile memory 1104 and processing device 1102 can also constitute machine-readable storage media.

While computer-readable storage medium 1124 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein can be implemented by discrete hardware components or can be integrated in the functionality of other hardware components such as ASICS, FPGAs, DSPs or similar devices. In addition, the methods, components, and features can be implemented by firmware modules or functional circuitry within hardware devices. Further, the methods, components, and features can be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and cannot have an ordinal meaning according to their numerical designation.

Examples described herein also relate to an apparatus for performing the methods described herein. This apparatus can be specially constructed for performing the methods described herein, or it can include a general purpose computer system selectively programmed by a computer program stored in the computer system. Such a computer program can be stored in a computer-readable tangible storage medium.

The methods and illustrative examples described herein are not inherently related to any particular computer or other apparatus. Various general purpose systems can be used in accordance with the teachings described herein, or it can prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A monitoring system, comprising:
a body to couple to a surface of a tool for an electronic device manufacturing system;
a vibration detecting sensor disposed in or on the body, the vibration detecting sensor to generate a signal based on a vibration of the surface;
a wired communication device disposed in or on the body, wherein the wired communication device is configured to transmit the signal generated by the vibration detecting sensor to a computer system via a wired connection with the computer system; and
a wireless communication device disposed in or on the body, wherein the wireless communication device is configured to establish a wireless connection with the computer system and to transmit the signal generated by the vibration detecting sensor to the computer system via the wireless connection.

2. The monitoring system of claim 1, wherein the body comprises a flexible substrate that is to conform to a shape of the surface.

3. The monitoring system of claim 1, further comprising:
a signal processing component configured to at least one of: 1) convert the signal generated by the vibration detecting sensor into acceleration data, 2) amplify one or more characteristics of the signal generated by the vibration detecting sensor, or 3) perform one or more filtering operations on the signal generated by the vibration detecting sensor.

4. The monitoring system of claim 1, wherein the computer system is to execute an application providing a graphical user interface (GUI) to present vibration measurements.

5. The monitoring system of claim 4, wherein the computer system is to convert the signal received from the wired communication device or the wireless communication device to at least one of velocity data or displacement data for display on the GUI.

6. The monitoring system of claim 4, wherein the computer system is to apply a Fast Fourier transform to transform the signal received from the wired communication device or the wireless communication device into a frequency domain for display on the GUI.

7. The monitoring system of claim 1, wherein the computer system is to apply at least one of a high pass filter or a low pass filter to the signal.

8. The monitoring system of claim 1, further comprising:
a battery disposed on the substrate, the battery having a mass at least ten times less than a mass of the monitoring system.

9. The monitoring system of claim 1, further comprising:
a power component disposed on the substrate, the power component to:
receive a first voltage;
convert the first voltage to a second voltage that is lower than the first voltage; and
apply the second voltage to the vibration detecting sensor.

10. The monitoring system of claim 1, wherein the tool comprises metrology equipment that is coupled to a least one of a process chamber or a transfer chamber.

11. The monitoring system of claim 1, wherein the vibration detecting sensor is an accelerometer.

12. The monitoring system of claim 1, wherein a weight of monitoring system is configured to maintain or increase a resonance frequency of the vibration detecting sensor.

13. An electronic device manufacturing system, comprising:
a tool; and
a monitoring system coupled to the tool, the monitoring system comprising:
a body to couple to a surface of the tool;
a vibration detecting sensor disposed in or on the body, the vibration detecting sensor to generate a signal based on a vibration of the surface;
a wired communication device disposed in or on the body, wherein the wired communication device is configured to transmit the signal generated by the vibration detecting sensor to a computer system via a wired connection with the computer system; and
a wireless communication device disposed in or on the body, wherein the wireless communication device is configured to establish a wireless connection with the computer system and to transmit the signal generated by the vibration detecting sensor to the computer system via the wireless connection.

14. The electronic device manufacturing system of claim 13, wherein the body comprises a flexible substrate that is to conform to a shape of the surface.

15. The electronic device manufacturing system of claim 13, wherein the monitoring system further comprises: a signal processing component configured to at least one of: 1) convert the signal generated by the vibration detecting sensor into acceleration data, 2) amplify one or more characteristics of the signal generated by the vibration detecting sensor, or 3) perform one or more filtering operations on the signal generated by the vibration detecting sensor.

16. The electronic device manufacturing system of claim 13, wherein the computer system is to execute an application providing a graphical user interface (GUI) to present vibration measurements.

17. The electronic device manufacturing system of claim 13, wherein the monitoring system further comprises a power component disposed on the substrate, the power component to:
receive a first voltage;
convert the first voltage to a second voltage that is lower than the first voltage; and
apply the second voltage to the vibration detecting sensor.

18. The electronic device manufacturing system of claim 13, wherein the tool comprises metrology equipment that is coupled to a least one of a process chamber or a transfer chamber.

19. The electronic device manufacturing system of claim 13, wherein a weight of monitoring system is configured to maintain or increase a resonance frequency of the vibration detecting sensor.

20. A method, comprising:
generating, by a monitoring system mounted to a tool of an electronic device manufacturing system, vibration data associated with the tool, wherein the monitoring system comprises:
a body to couple to a surface of the tool;
a vibration detecting sensor disposed in or on the body, the vibration detecting sensor to generate a signal based on a vibration of the surface;
a wired communication device disposed in or on the body, wherein the wired communication device is configured to transmit the signal generated by the vibration detecting sensor to the computer system via a wired connection with a computer system; and
a wireless communication device disposed in or on the body, wherein the wireless communication device is configured to establish a wireless connection with the computer system and to transmit the signal generated by the vibration detecting sensor to the computer system via the wireless connection.
